(19) United States
(12) Patent Application Publication
(10) Pub. No.: US 2025/0328700 A1
(43) Pub. Date: Oct. 23, 2025

(54) INFORMATION PROCESSING SYSTEM, INFORMATION PROCESSING METHOD, AND NON-TRANSITORY STORAGE MEDIUM STORING INFORMATION PROCESSING PROGRAM

(71) Applicant: TOYOTA JIDOSHA KABUSHIKI KAISHA, Toyota-shi (JP)

(72) Inventors: Kanade KURIYAMA, Toyota-shi (JP); Masataka OKUDA, Toyota-shi (JP); Kaoru YOSHIDA, Nisshin-shi (JP); Toshiki SHINOHARA, Toyota-shi (JP); Masatoshi KAKUTANI, Miyoshi-shi (JP)

(73) Assignee: TOYOTA JIDOSHA KABUSHIKI KAISHA, Toyota-shi (JP)

(21) Appl. No.: 19/085,094

(22) Filed: Mar. 20, 2025

(30) Foreign Application Priority Data
Apr. 19, 2024 (JP) 2024-068479

(51) Int. Cl. G06F 30/13; G08G 1/01; G08G 1/052

(52) U.S. Cl. CPC G06F 30/13; G08G 1/0112; G08G 1/052

(57) ABSTRACT

An information processing system is configured to acquire moving body information at a set cycle. The moving body information indicates a position of each of multiple moving bodies located in the real world. The information processing system is configured to calculate predicted moving body information based on the moving body information. The predicted moving body information indicates a predicted position of each of the moving bodies at a time after the moving body information was acquired. The information processing system is configured to acquire, using the moving body information, information related to a density of the moving bodies located within a set zone. The information processing system is configured to determine a cycle using information related to the density.

### CROSS-REFERENCE TO RELATED APPLICATIONS

This application is based upon and claims the benefit of priority from Japanese Patent Application No. 2024-068479, filed on Apr. 19, 2024, the entire contents of which are incorporated herein by reference.

### BACKGROUND

### 1. Field

The present disclosure relates to an information processing system, an information processing method, and a non-transitory storage medium storing an information processing program for reproducing a real-world traffic environment in a virtual space.

### 2. Description of Related Art

A digital twin is a technology that reproduces an environment identical to the real world in a virtual space. Japanese Laid-Open Patent Publication No. 2020-013557 discloses a system that utilizes a traffic digital twin to reproduce a real-world traffic environment in a virtual space.

To accurately reproduce the real-world positions of moving bodies in a virtual space, one approach is to minimize the cycle for acquiring information that indicates the positions of the moving bodies. However, this would increase the processing load on the device that processes the acquired information indicating the positions of the moving bodies and reproducing the positions of the moving bodies in the virtual space.

### SUMMARY

This Summary is provided to introduce a selection of concepts in a simplified form that are further described below in the Detailed Description. This Summary is not intended to identify key characteristics or essential characteristics of the claimed subject matter, nor is it intended to be used as an aid in determining the scope of the claimed subject matter.

An information processing system according to an aspect of the present disclosure is configured to acquire moving body information at a set cycle. The moving body information indicates a position of each of multiple moving bodies located in the real world. The information processing system is configured to calculate predicted moving body information based on the moving body information. The predicted moving body information indicates a predicted position of each of the moving bodies at a time after the moving body information was acquired. The information processing system is configured to acquire, using the moving body information, information related to a density of the moving bodies located within a set zone. The information processing system is configured to determine the cycle using the information related to the density.

An information processing method according to an aspect of the present disclosure includes acquiring moving body information at a set cycle. The moving body information indicates a position of each of multiple moving bodies located in the real world. The information processing method includes calculating predicted moving body information based on the moving body information. The predicted moving body information indicates a predicted position of each of the moving bodies at a time after the moving body information was acquired. The information processing method includes acquiring, using the moving body information, information related to a density of the moving bodies located within a set zone. The information processing method includes determining the cycle using the information related to the density.

A non-transitory storage medium that stores an information processing program according to an aspect of the present disclosure is provided. The information processing program causes processing circuitry to execute acquiring moving body information at a set cycle. The moving body information indicates a position of each of multiple moving bodies located in the real world. The information processing program causes the processing circuitry to execute calculating predicted moving body information based on the moving body information. The predicted moving body information indicates a predicted position of each of the moving bodies at a time after the moving body information was acquired. The information processing program causes the processing circuitry to execute acquiring, using the moving body information, information related to a density of the moving bodies located within a set zone. The information processing program causes the processing circuitry to execute determining the cycle using the information related to the density.

Other features and aspects will be apparent from the following detailed description, the drawings, and the claims.

### BRIEF DESCRIPTION OF THE DRAWINGS

FIG. 1 is a schematic diagram illustrating an information processing system according to a first embodiment.

FIG. 2 is a schematic diagram illustrating the processing device, the communication device, and the storage device of the information processing system shown in FIG. 1.

FIG. 3 is a sequence diagram illustrating the communication executed by the information processing system and sensors of the first embodiment.

FIG. 4 is a flowchart illustrating a series of processes executed by the information processing system shown in FIG. 3.

FIG. 5 is a schematic diagram illustrating the moving bodies located within the set zones in the first embodiment.

FIG. 6 is a sequence diagram illustrating the communication executed by the information processing system and sensors according to a second embodiment.

FIG. 7 is a flowchart illustrating a series of processes executed by the information processing system shown in FIG. 6.

FIG. 8 is a schematic diagram illustrating the moving bodies located within the set zones in the second embodiment.

FIG. 9 is a schematic diagram showing the configuration of a trained model according to a third embodiment.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### First Embodiment

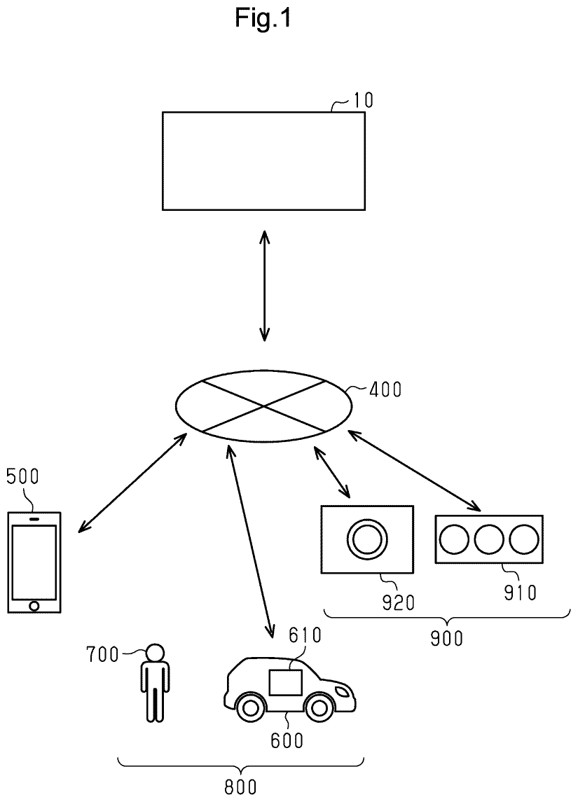

An information processing system 10 according to a first embodiment will now be described with reference to FIGS. 1 to 5.

### Overview of Information Processing System 10

The information processing system 10 acquires moving body information, which indicates the position of each of multiple moving bodies 800 in the real world, at multiple times. Examples of the moving bodies 800 include vehicles 600, pedestrians 700, bicycles, and animals. The vehicles 600 include two-wheeled vehicles.

The information processing system 10 acquires, using the acquired moving body information, predicted moving body information at a set update cycle. The predicted moving body information indicates the predicted position and predicted behavior of each moving body 800 at a time after the moving body information was acquired. The predicted moving body information reproduces the real-world traffic environment in a virtual space.

As shown in FIG. 1, the information processing system 10 is configured to communicate with multiple information processing terminals 500 (only one is shown), multiple vehicles 600 (only one is shown), and multiple roadside sensors 900 via an external communication network 400.

The information processing terminal 500 is capable of collecting the position information of a pedestrian 700 carrying the information processing terminal 500 as moving body information. The position information is represented by coordinate values of latitude and longitude. The information processing terminal 500 is capable of transmitting the collected position information of the pedestrian 700 to the information processing system 10 via the external communication network 400. Examples of the information processing terminal 500 include a smartphone carried by the pedestrian 700. Examples of the information processing terminal 500 may include a wearable terminal and a tablet terminal. Examples of the wearable terminal include a ring-type terminal worn on the wrist and a necklace-type terminal worn around the neck.

The vehicle 600 includes a vehicle on-board sensor 610. The vehicle 600 transmits the moving body information collected by the vehicle on-board sensor 610 to the information processing system 10 via the external communication network 400. Examples of the vehicle on-board sensor 610 include a vehicle speed sensor, an accelerator sensor, a brake sensor, a steering sensor, and an acceleration sensor. The acceleration sensor is, for example, an inertial measurement unit (IMU).

The vehicle 600 further includes an external camera, a sonar, and a position information acquisition system as the vehicle on-board sensor 610. The external camera and the sonar mounted on the vehicle 600 collect information related to the distance DIS between the vehicle 600 and one or more other objects located around the vehicle 600, thereby generating observational data. The vehicle 600 may include a light detection and ranging (LiDAR) sensor as a sensor that has the same features as those of the external camera and the sonar. Examples of the position information acquisition system include a global navigation satellite system (GNSS), a real-time kinematic (RTK)-enabled device, and a LiDAR sensor.

The vehicle on-board sensors 610 collect moving body information, including vehicle information such as a vehicle identification number (VIN) of the vehicle 600 and information on a vehicle speed, a travel direction, and a travel route and the position of the vehicle 600.

The roadside sensors 900 are installed on the road. The roadside sensors 900 include, for example, multiple traffic lights 910, multiple roadside cameras 920, and LiDAR sensors installed on the road. Each traffic light 910 transmits information related to changes in the state of the traffic infrastructure, such as the time at which the traffic light 910 turns green and the time during which the traffic light 910 remains green, to the information processing system 10 via the external communication network 400.

Each roadside camera 920 collects observational data around the roadside camera 920. The observational data includes the moving body information of the moving bodies 800 located around each roadside camera 920. Examples of the roadside cameras 920 include visible light cameras and infrared cameras. The LiDAR sensors installed on the road acquire point cloud datasets arranged in chronological order, by continuously observing the moving body 800 at fixed time intervals. Each LiDAR sensor collects the moving body information of the moving bodies 800 located around the LiDAR sensor.

### Providing Traffic Services Based on Predicted Moving Body Information

The information processing system 10 is capable of transmitting predicted moving body information to the vehicle 600. The vehicle 600 is capable of providing the user of the vehicle 600 with traffic services based on the predicted moving body information acquired by the information processing system 10. The vehicle 600 includes vehicle on-board processing circuitry, a braking system, a steering system, directional indicators, speakers, and displays as vehicle on-board devices. The display of the vehicle 600 presents traffic services to the user of the vehicle 600. For example, the vehicle on-board processing circuitry uses the predicted moving body information to display a vehicle approach notification and traffic information on the displays of the vehicle 600. For example, the vehicle on-board processing circuitry uses the predicted moving body information to issue a vehicle approach alert to the user of the vehicle 600 via the speakers of the vehicle 600. For example, the vehicle on-board processing circuitry uses the predicted moving body information to control the braking system of the vehicle 600, thereby decelerating or stopping the vehicle 600. For example, the vehicle on-board processing circuitry uses the predicted moving body information to control the steering system of the vehicle 600, thereby controlling the steering of the vehicle 600. The vehicle on-board processing circuitry may also control the directional indicators in addition to controlling the steering.

The information processing system 10 is capable of transmitting predicted moving body information to the information processing terminal 500. The information processing terminal 500 is capable of providing traffic services to the user of the information processing terminal 500 based on the predicted moving body information acquired by the information processing system 10. For example, the information processing terminal 500 uses the predicted moving body information to show a vehicle approach notification and traffic information on the display of the information processing terminal 500.

The information processing system 10 is capable of transmitting predicted moving body information to the traffic light 910. The traffic light 910 is capable of controlling its operation based on the predicted moving body information acquired by the information processing system 10. For example, the traffic light 910 is capable of controlling the time at which the traffic light 910 turns green and the time during which the traffic light 910 remains green based on the predicted moving body information. This enables the information processing system 10 to facilitate smooth traffic flow.

### Configuration of Information Processing System 10

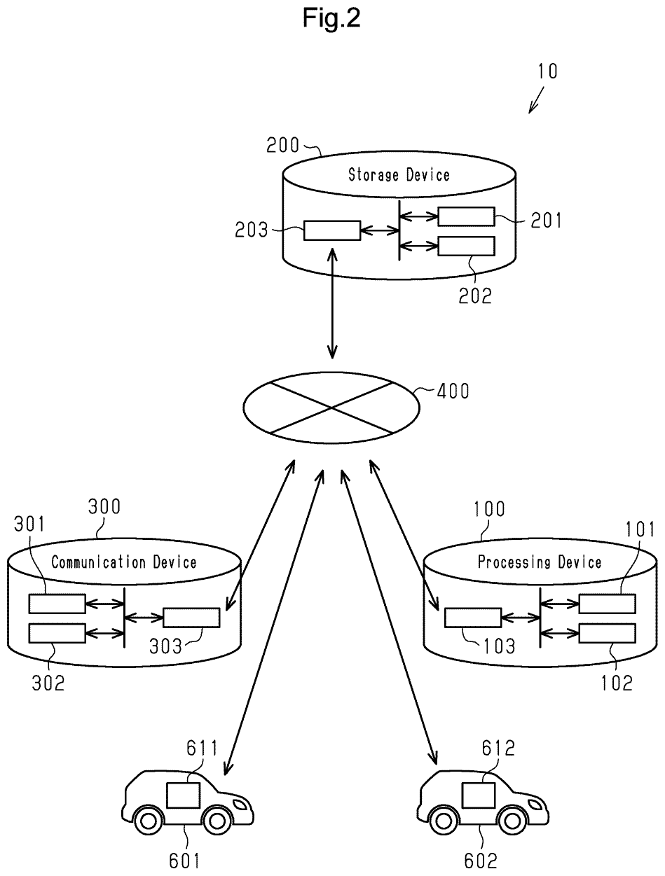

As illustrated in FIG. 2, the information processing system 10 includes a processing device 100, a storage device 200, and a communication device 300.

The processing device 100 includes first processing circuitry 101, first storage circuitry 102, and first communication circuitry 103. The first storage circuitry 102 stores programs. The first processing circuitry 101 executes the programs stored in the first storage circuitry 102 to execute various types of processes. The first processing circuitry 101 includes one or more processors. The processing device 100 is connected to the external communication network 400 via the first communication circuitry 103.

The storage device 200 includes second processing circuitry 201, second storage circuitry 202, and second communication circuitry 203. The second storage circuitry 202 stores programs. The second processing circuitry 201 executes the programs stored in the second storage circuitry 202 to execute various types of processes. The second processing circuitry 201 includes one or more processors. The storage device 200 is connected to the external communication network 400 via the second communication circuitry 203.

The communication device 300 includes third processing circuitry 301, third storage circuitry 302, and third communication circuitry 303. The third storage circuitry 302 stores programs. The third processing circuitry 301 executes the programs stored in the third storage circuitry 302 to execute various types of processes. The third processing circuitry 301 includes one or more processors. The communication device 300 is connected to the external communication network 400 via the third communication circuitry 303.

Each of the first processing circuitry 101, the second processing circuitry 201, and the third processing circuitry 301 may include hardware circuitry including one or more dedicated hardware circuits such as an application-specific integrated circuit (ASIC) that execute at least some of the various processes or a combination thereof. Alternatively, each of the first processing circuitry 101, the second processing circuitry 201, and the third processing circuitry 301 may include a combination of one or more processors and one or more dedicated hardware circuits. Each of the first storage circuitry 102, the second storage circuitry 202, and the third storage circuitry 302 includes a memory such as a RAM and a ROM. The memory, or a computer-readable medium, includes any type of media that are accessible by general-purpose computers and dedicated computers.

The configuration of the information processing system 10 is not limited to the one shown in FIG. 2. For example, the processing device 100, the storage device 200, and the communication device 300 may be included in a single server. For example, the processing device 100, the storage device 200, and the communication device 300 may be wired to each other in a manner that allows mutual communication.

FIG. 2 illustrates a first vehicle 601 and a second vehicle 602 as examples of the moving bodies 800 for which the information processing system 10 acquires predicted moving body information. The first vehicle 601 includes a first vehicle on-board sensor 611 that transmits the moving body information of the first vehicle 601 to the information processing system 10 via the external communication network 400. In the same manner, the second vehicle 602 includes a second vehicle on-board sensor 612 that transmits the moving body information of the second vehicle 602 to the information processing system 10 via the external communication network 400.

The communication device 300 acquires the moving body information transmitted from sensors at a set transmission cycle via the third communication circuitry 303. The communication device 300 stores the acquired moving body information in the third storage circuitry 302. The third processing circuitry 301 of the communication device 300 transmits the moving body information stored in the third storage circuitry 302 to the processing device 100 via the third communication circuitry 303.

The processing device 100 acquires the moving body information from the communication device 300 via the first communication circuitry 103. The processing device 100 stores the received moving body information in the first storage circuitry 102. The first processing circuitry 101 of the processing device 100 acquires predicted moving body information using the moving body information. The processing device 100 transmits the predicted moving body information to the storage device 200 via the first communication circuitry 103.

The storage device 200 receives the predicted moving body information via the second communication circuitry 203. The storage device 200 stores the acquired predicted moving body information in the second storage circuitry 202. In response to a request via the external communication network 400, the second processing circuitry 201 of the storage device 200 provides the predicted moving body information stored in the second storage circuitry 202 to the information processing terminal 500, the vehicle 600, and the traffic light 910.

The processing device 100 of the information processing system 10 uses the acquired moving body information to determine a collection time, at which each sensor should start collecting the moving body information. The processing device 100 uses the acquired moving body information to determine a collection cycle, at which each sensor should collect the moving body information. The processing device 100 uses the acquired moving body information to determine a transmission time, at which each sensor should start transmitting the moving body information. The processing device 100 uses the acquired moving body information to determine a transmission cycle, at which each sensor should transmit the moving body information. The information processing system 10 transmits the collection time, the collection cycle, the transmission time, and the transmission cycle determined by the processing device 100 to each sensor via the communication device 300 and the external communication network 400. For example, the information processing system 10 transmits the collection time, the collection cycle, the transmission time, and the transmission cycle determined by the processing device 100 to the first vehicle on-board sensor 611 and the second vehicle on-board sensor 612, which are sown in FIG. 2. As a result, the information processing system 10 determines the cycle for acquiring moving body information. The transmission of the collection time, the collection cycle, the transmission time, and the transmission cycle may be performed using over-the-air (OTA) technology.

### Communication Between Information Processing System 10 and Sensors in First Embodiment

In the first embodiment, the information processing system 10 synchronizes the collection times of multiple sensors located within a set zone. The information processing system 10 aligns the collection cycles of the sensors located within the set zone. The information processing system 10 synchronizes the transmission times of the sensors located within the set zone. The information processing system 10 aligns the transmission cycles of the sensors located within the set zone. As a result, the information processing system 10 acquires the moving body information of the moving bodies 800 located within the set zone from the sensors at the same time and at the same cycle.

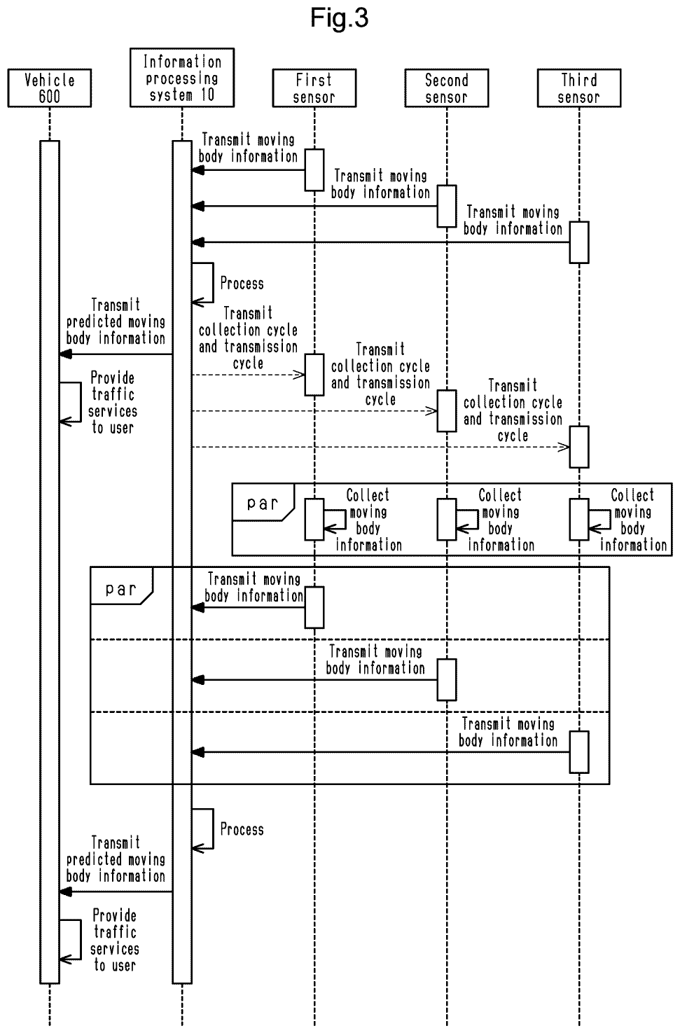

FIG. 3 illustrates the communication between the information processing system 10 and multiple sensors in the first embodiment. In the example of FIG. 3, a first sensor, a second sensor, and a third sensor first transmit moving body information to the information processing system 10.

After receiving the moving body information from the sensors via the communication device 300, the information processing system 10 executes a process that acquires predicted moving body information based on the received moving body information. Then, the information processing system 10 transmits the predicted moving body information to the vehicle 600. After acquiring the predicted moving body information, the vehicle 600 provides traffic services to the user of the vehicle 600 based on the predicted moving body information.

After receiving the moving body information from the sensors via the communication device 300, the information processing system 10 executes a process that determines the collection time, the collection cycle, the transmission time, and the transmission cycle based on the acquired moving body information. The information processing system 10 transmits the determined collection time, the collection cycle, the transmission time, and the transmission cycle to each sensor.

The times at which the moving body information starts to be collected and the cycles at which the moving body information is collected are synchronized with each other between the sensors that have received the collection time and the collection cycle determined by the information processing system 10. Namely, the first sensor, the second sensor, and the third sensor collect the moving body information at the same time. After collecting the moving body information, the first sensor, the second sensor, and the third sensor transmit the collected moving body information to the information processing system 10. The times at which the moving body information starts to be transmitted and the cycles at which the moving body information is transmitted are synchronized with each other between the sensors that have received the transmission time and the transmission cycle determined by the information processing system 10. Thus, the first sensor, the second sensor, and the third sensor transmit the collected moving body information to the information processing system 10 at the same time.

After receiving the moving body information from the sensors via the communication device 300 at the same time, the information processing system 10 executes a process that acquires predicted moving body information based on the received moving body information. The information processing system 10 transmits the predicted moving body information to the vehicle 600. After acquiring the predicted moving body information, the vehicle 600 provides traffic services to the user of the vehicle 600 based on the predicted moving body information.

### Determination of Collection Cycle and Transmission Cycle for Sensors by Information Processing System 10 of First Embodiment

In the first embodiment, the information processing system 10 determines the collection cycle and the transmission cycle for each sensor based on the number QTY of moving bodies 800 per unit area, which is information related to the density of the moving bodies 800.

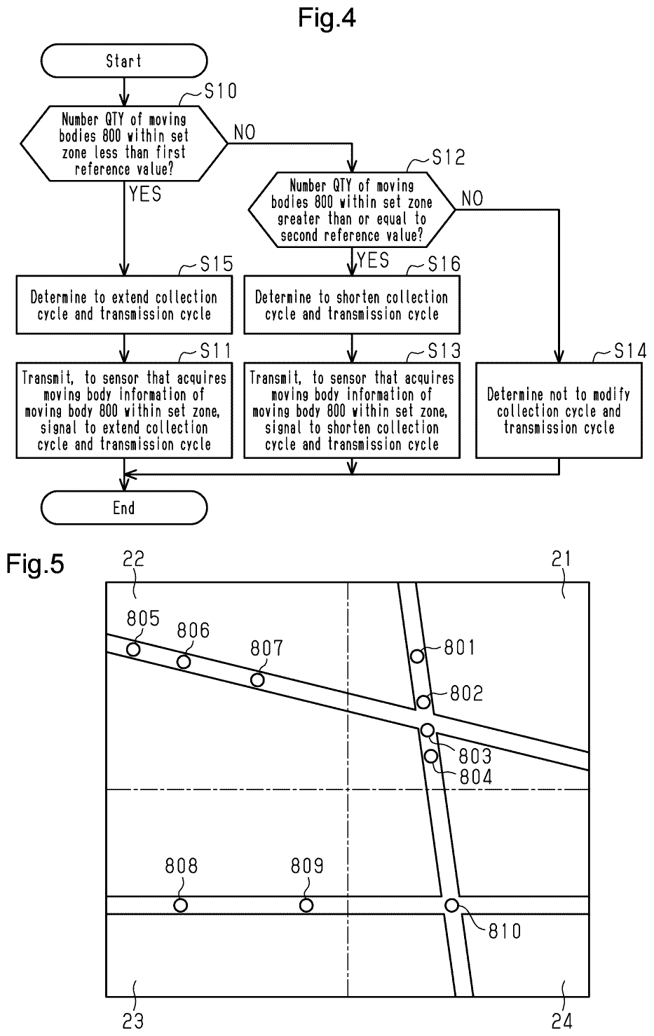

FIG. 4 is a flowchart illustrating a series of processes executed by the processing device 100 of the information processing system 10. The first storage circuitry 102 of the processing device 100 stores a program that causes the first processing circuitry 101 to execute the series of processes. The processing device 100 executes the series of processes, which are shown in FIG. 4, according to the program stored in the first storage circuitry 102. The series of processes is executed repeatedly by the information processing system 10 at regular intervals.

FIG. 5 illustrates the zones for which the information processing system 10 determines the collection time, the collection cycle, the transmission time, and the transmission cycle for the sensors. FIG. 5 illustrates four zones; namely, a first zone 21, a second zone 22, a third zone 23, and a fourth zone 24. The first zone 21, the second zone 22, the third zone 23, and the fourth zone 24 are defined based on latitude and longitude information. In the first embodiment, the first zone 21, the second zone 22, the third zone 23, and the fourth zone 24 each have the same area. In the first embodiment, each of the areas of the first zone 21, the second zone 22, the third zone 23, and the fourth zone 24 is defined as a unit area.

Zones do not have to be defined based on latitude and longitude information. That is, zones may be defined as any range. For the information processing system 10 to determine the collection cycle and the transmission cycle for each sensor, the unit area may be set to any size.

The first zone 21 contains a first moving body 801, a second moving body 802, a third moving body 803, and a fourth moving body 804. Namely, there are four moving bodies 800 per unit area in the first zone 21. The second zone 22 contains a fifth moving body 805, a sixth moving body 806, and a seventh moving body 807. Namely, there are three moving bodies 800 per unit area in the second zone 22. The third zone 23 contains an eighth moving body 808 and a ninth moving body 809. Namely, there are two moving bodies 800 per unit area in the third zone 23. The fourth zone 24 contains a tenth moving body 810. Namely, there is one moving body 800 per unit area in the fourth zone 24.

Upon starting the series of processes shown in FIG. 4, the processing device 100 determines in the process of step S10 whether the number QTY of moving bodies 800 located within the set zone is less than a first reference value. In the first embodiment, the information processing system 10 sets the first reference value to two per unit area. When the number QTY of moving bodies 800 within the set zone is less than the first reference value (step S10: YES), for example, when the number QTY of moving bodies 800 within the set zone is one, the process proceeds to step S15. In the process of step S15, the information processing system 10 determines to extend the collection cycle and the transmission cycle for a sensor that acquires the moving body information of the moving body 800 within the zone. Subsequently, the process proceeds to step S11. In the process of step S11, the information processing system 10 transmits a signal to extend the collection cycle and the transmission cycle to a sensor that acquires the moving body information of the moving body 800 within the zone. Then, the information processing system 10 terminates the process.

As shown in FIG. 5, there is one moving body 800 per unit area in the fourth zone 24. Accordingly, upon executing the series of processes shown in FIG. 4, the information processing system 10 determines to extend the collection cycle and the transmission cycle for the sensor that acquires the moving body information of the tenth moving body 810, which is located in the fourth zone 24. Then, the information processing system 10 transmits a signal to extend the collection cycle and the transmission cycle to the sensor that acquires the moving body information of the tenth moving body 810, which is located in the fourth zone 24. As a result, the cycle for acquiring the moving body information of the moving body 800 located in the fourth zone 24 by the information processing system 10 is extended.

In the series of processes shown in FIG. 4, when the number QTY of the moving body 800 within the set zone is greater than or equal to the first reference value (step S10: NO), the process proceeds to step S12. In the process of step S12, the information processing system 10 determines whether the number QTY of moving bodies 800 within the set zone is greater than or equal to the second reference value. The second reference value is greater than the first reference value. In the first embodiment, the information processing system 10 sets the second reference value to three per unit area.

When the number QTY of moving bodies 800 within the set zone is greater than or equal to the second reference value (step S12: YES), the process proceeds to step S16. In the process of step S16, the information processing system 10 determines to shorten the collection cycle and the transmission cycle for a sensor that acquires the moving body information of the moving body 800 within the zone. The process then proceeds to step S13. In the process of step S13, the information processing system 10 transmits a signal to shorten the collection cycle and the transmission cycle to a sensor that acquires the moving body information of the moving body 800 within the zone. Then, the information processing system 10 terminates the process.

As shown in FIG. 5, there are four moving bodies 800 per unit area in the first zone 21. Accordingly, upon executing the processes shown in FIG. 4, the information processing system 10 determines to shorten the collection cycle and the transmission cycle for the sensor that acquires the moving body information of the moving body 800 located in the first zone 21. Then, the information processing system 10 transmits a signal to shorten the collection cycle and the transmission cycle to the sensor that acquires the moving body information of the moving body 800 located in the first zone 21. There are three moving bodies 800 per unit area in the second zone 22. Accordingly, upon executing the series of processes shown in FIG. 4, the information processing system 10 determines to shorten the collection cycle and the transmission cycle for the sensor that acquires the moving body information of the moving body 800 located in the second zone 22. Then, the information processing system 10 transmits a signal to shorten the collection cycle and the transmission cycle to the sensor that acquires the moving body information of the moving body 800 located in the second zone 22. As a result, the cycle for acquiring the moving body information of the moving body 800 located in the second zone 22 by the information processing system 10 is shortened.

In the series of processes shown in FIG. 4, when the number QTY of moving bodies 800 within the set zone is less than the second reference value (step S12: NO), that is, when the number of moving bodies 800 within the set zone is two in the first embodiment, the process proceeds to step S14. In the process of step S14, the information processing system 10 determines not to modify the collection cycle and the transmission cycle for a sensor that acquires the moving body information of the moving body 800 within the zone. In this case, the information processing system 10 does not transmit a signal to a sensor that acquires the moving body information of the moving body 800 within the zone. Then, the information processing system 10 terminates the process.

As shown in FIG. 5, there are two moving bodies 800 per unit area in the third zone 23. Accordingly, upon executing the series of processes shown in FIG. 4, the information processing system 10 determines not to modify the collection cycle and the transmission cycle for the sensor that acquires the moving body information of the moving body 800 located in the third zone 23. In this case, the information processing system 10 does not transmit a signal to a sensor that acquires the moving body information of the moving body 800 located in the third zone 23. As a result, the cycle for acquiring the moving body information of the moving body 800 located in the third zone 23 by the information processing system 10 is not modified.

### Operation of First Embodiment

When the number QTY of moving bodies 800 per unit area is relatively large, in other words, when the density of the moving bodies 800 is relatively high, the behavior of a moving body 800 is more likely to affect the behavior of the other moving bodies 800. As a result, it is difficult for the information processing system 10 to acquire accurate predicted moving body information. To acquire accurate predicted moving body information when the density of moving bodies 800 is relatively high, the information processing system 10 needs to obtain the moving body information of the moving bodies 800 at relatively short cycles. When the number QTY of moving bodies 800 per unit area is relatively small, in other words, when the density of the moving bodies 800 is relatively low, the behavior of a moving body 800 is less likely to affect the behavior of the other moving bodies 800. Thus, even if the cycle for acquiring moving body information is relatively long, the information processing system 10 acquires accurate predicted moving body information for each moving body 800.

### Advantages of First Embodiment

(1-1) The information processing system 10 determines the cycle for acquiring moving body information based on the number QTY of moving bodies 800 per unit area, which is information related to the density of the moving bodies 800. This reduces the processing load on the information processing system 10 that acquires the predicted moving body information based on the moving body information.

(1-2) The information processing system 10 makes the times at which multiple sensors collect moving body information identical and determines the identical collection time. The information processing system 10 makes the cycles at which the sensors collect the moving body information identical and determines the identical collection cycle. This allows the information processing system 10 to acquire, without any loss, the moving body information at a certain moment for the moving bodies 800 located within the set zone from all the sensors that collect the moving body information of the moving bodies 800 located within the set zone. As a result, the information processing system 10 acquires accurate predicted moving body information based on the moving body information of the moving bodies 800 within the set zone, which has been acquired without any loss.

(1-3) When the number QTY of moving bodies 800 per unit area is relatively small, the behavior of a moving body 800 is less likely to affect the behavior of the other moving bodies 800. Thus, even if the cycle for acquiring moving body information is relatively long, the information processing system 10 acquires accurate predicted moving body information for each moving body 800. Therefore, the information processing system 10 extends the cycle for acquiring moving body information on condition that the number QTY of moving bodies 800 located in the set zone is less than the first reference value. Such a configuration reduces the frequency for the information processing system 10 to acquire the predicted moving body information based on the moving body information. This reduces the processing load on the information processing system 10 that acquires the predicted moving body information based on the moving body information.

(1-4) When the number QTY of moving bodies 800 per unit area is relatively large, the behavior of a moving body 800 is more likely to affect the behavior of the other moving bodies 800. Thus, when the number QTY of moving bodies 800 per unit area is relatively large, the information processing system 10 needs to acquire moving body information at a higher frequency to accurately reproduce the positions of the moving bodies 800 in the virtual space that correspond to those in the real world. When the information processing system 10 has a relatively short cycle for acquiring moving body information, the amount of the moving body information acquired per unit time by the information processing system 10 increases. As a result, the processing load on the information processing system 10 increases. To solve this problem, the information processing system 10 shortens the cycle for acquiring moving body information on condition that the number QTY of moving bodies 800 per unit area is greater than or equal to the second reference value. The cycle for acquiring the moving body information is shortened based on the number QTY of moving bodies 800 per unit area being greater than or equal to the second reference value. This allows the information processing system 10 to accurately reproduce the position of each moving body 800 in the virtual space without increasing the processing load.

(1-5) The information processing method executed by the information processing system 10 includes the step in which the communication device 300 acquires moving body information, which indicates the position of each moving body 800 in the real world, in the set cycle. The information processing method executed by the information processing system 10 includes the step in which the processing device 100 acquires predicted moving body information, which indicates the predicted position of each moving body 800, at a time after the moving body information was acquired, based on the moving body information. The information processing method executed by the information processing system 10 includes the step in which the processing device 100 acquires the number QTY of moving bodies 800 per unit area, which is information related to the density of moving bodies 800 in the set zone, using the moving body information. The information processing method executed by the information processing system 10 includes the step in which the processing device 100 determines the collection cycle and the transmission cycle for the sensor using the number QTY of the moving bodies 800 per unit area. By executing such an information processing method, the information processing system 10 determines the cycle for acquiring moving body information based on the number QTY of the moving bodies 800 per unit area. This reduces the processing load on the information processing system 10 that acquires the predicted moving body information based on the moving body information.

(1-6) The first storage circuitry 102 of the processing device 100 of the information processing system 10 stores an information processing program that causes the first processing circuitry 101 of the processing device 100 to execute processes. The information processing program causes the first processing circuitry 101 of the processing device 100 to execute acquiring moving body information, which indicates the position of each moving body 800 in the real world, in the set cycle. The information processing program causes the first processing circuitry 101 of the processing device 100 to execute acquiring predicted moving body information, which indicates the predicted position of each moving body 800 at a time after the moving body information was acquired, based on the moving body information. The information processing program causes the first processing circuitry 101 of the processing device 100 to execute acquiring the number QTY of moving bodies 800 per unit area, which is information related to the density of moving bodies 800 in the set zone, using the moving body information. The information processing program causes the first processing circuitry 101 of the processing device 100 to execute determining the collection cycle and the transmission cycle using the information related to the density. By executing such an information processing program, the information processing system 10 determines the cycle for acquiring moving body information based on the number QTY of the moving bodies 800 per unit area. This reduces the processing load on the information processing system 10 that acquires the predicted moving body information based on the moving body information.

### Modification of First Embodiment

The first embodiment may be modified as follows. The present embodiment and the following modifications can be combined if the combined modifications remain technically consistent with each other.

The information processing system 10 does not have to make the collection times, the collection cycles, the transmission times, and the transmission cycles for multiple sensors within the set zone identical and determine the identical collection cycles and the transmission cycles for the sensors. For example, the information processing system 10 may determine the collection cycle and the transmission cycle for each sensor. In this case, the information processing system 10 may set a different collection cycle for each sensor. In this case, the information processing system 10 may set a different collection time for each sensor. The information processing system 10 may set a transmission cycle for each sensor. In this case, the information processing system 10 may set a different transmission time for each sensor.

The information processing system 10 does not have to determine the collection times for the sensors such that the moving body information of multiple moving bodies 800 start to be collected at the same time. For example, the information processing system 10 may determine the collection time for each sensor such that the moving body information of the eighth moving body 808 and the moving body information of the ninth moving body 809 start to be collected at a different time in the third zone 23, which is shown in FIG. 5.

After determining not to modify the collection cycle and the transmission cycle for the sensor that acquires the moving body information of a moving body 800 within the zone, the information processing system 10 may transmit a signal to the sensor, indicating that the collection cycle and the transmission cycle will not be modified. In such cases, the cycle at which the information processing system 10 acquires moving body information from the sensor will not be modified. The signal indicating no change will be made is, for example, a signal transmitted to a sensor to continue collecting and transmitting moving body information at the collection cycle and the transmission cycle in which the sensor is currently executing.

In the first embodiment, the information processing system 10 sets the first reference value and the second reference value. The information processing system 10 may be configured to set only one reference value. For example, the information processing system 10 may set the reference value to two per unit area. In this case, the information processing system 10 determines to extend the collection cycle and the transmission cycle for the sensors in a zone where the number QTY of moving bodies 800 per unit area is less than two. Then, the information processing system 10 transmits a signal to extend the collection cycle and the transmission cycle to the sensors in the zone where the number QTY of moving bodies 800 per unit area is less than two. The information processing system 10 determines to shorten the collection cycle and the transmission cycle for the sensors in a zone where the number QTY of moving bodies 800 per unit area is two or more. Then, the information processing system 10 transmits a signal to shorten the collection cycle and the transmission cycle to the sensors in the zone where the number QTY of moving bodies 800 per unit area is two or more.

The first reference value and the second reference value are not limited to those in the above-described embodiment. In the information processing system 10, the reference value may be set to any number QTY of moving bodies 800 in order to transmit suitable collection cycles and the transmission cycles to sensors.

### Second Embodiment

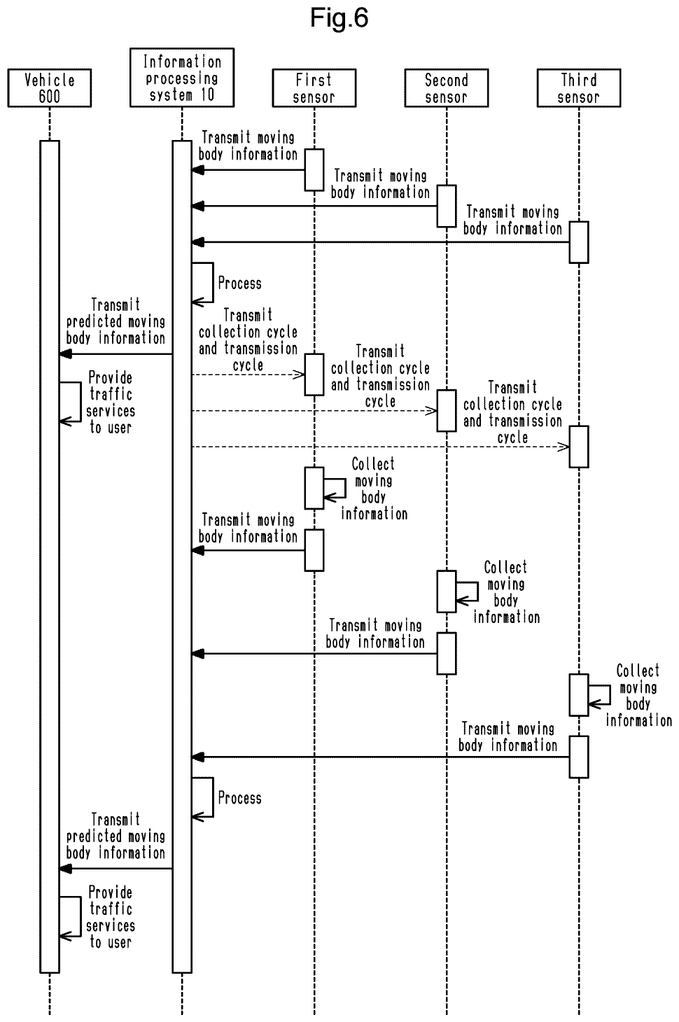

A second embodiment will now be described with reference to FIGS. 6 to 8. The second embodiment will be described, with a focus on the differences from the first embodiment.

### Communication Between Information Processing System 10 and Sensors in the Second Embodiment

In the second embodiment, the information processing system 10 determines the collection time, the collection cycle, the transmission cycle, and the transmission cycle for each sensor. This allows the information processing system 10 to acquire, from each sensor, the moving body information collected by the sensor at a suitable time and at a suitable cycle.

FIG. 6 illustrates the communication between the information processing system 10 and multiple sensors in the second embodiment. In the example of FIG. 6, the first sensor, the second sensor, and the third sensor first transmit moving body information to the information processing system 10.

After receiving the moving body information from the sensors via the communication device 300, the information processing system 10 executes a process that acquires predicted moving body information based on the received moving body information. Then, the information processing system 10 transmits the predicted moving body information to the vehicle 600. After receiving the predicted moving body information, the vehicle 600 provides traffic services to the user of the vehicle 600 based on the predicted moving body information.

After receiving the moving body information from the sensors, the information processing system 10 executes a process that determines the collection time, the collection cycle, the transmission time, and the transmission cycle for each sensor based on the received moving body information. The information processing system 10 transmits the collection time, the collection cycle, the transmission time, and the transmission cycle determined for each sensor to the first sensor, the second sensor, and the third sensor.

After receiving the collection cycle determined by the information processing system 10, the first sensor, the second sensor, and the third sensor each collect the moving body information according to the respective determined collection cycle. After receiving the transmission cycle determined by the information processing system 10, the first sensor, the second sensor, and the third sensor transmit the collected moving body information to the information processing system 10 according to the respective determined transmission cycle.

After receiving the moving body information via the communication device 300 from the sensors for which the collection cycle and the transmission cycle have been determined, the information processing system 10 executes a process that acquires predicted moving body information based on the received moving body information. The information processing system 10 transmits the predicted moving body information to the vehicle 600. After acquiring the predicted moving body information, the vehicle 600 provides traffic services to the user of the vehicle 600 based on the predicted moving body information.

In the second embodiment, the first sensor, the second sensor, and the third sensor may each have a different collection cycle. Further, the first sensor, the second sensor, and the third sensor may each have a different collection time. In the second embodiment, the first sensor, the second sensor, and the third sensor may each have a different transmission cycle. Further, the first sensor, the second sensor, and the third sensor may each have a different transmission time.

### Determination of Collection Cycle and Transmission Cycle for Sensors by the Information Processing System 10 of the Second Embodiment

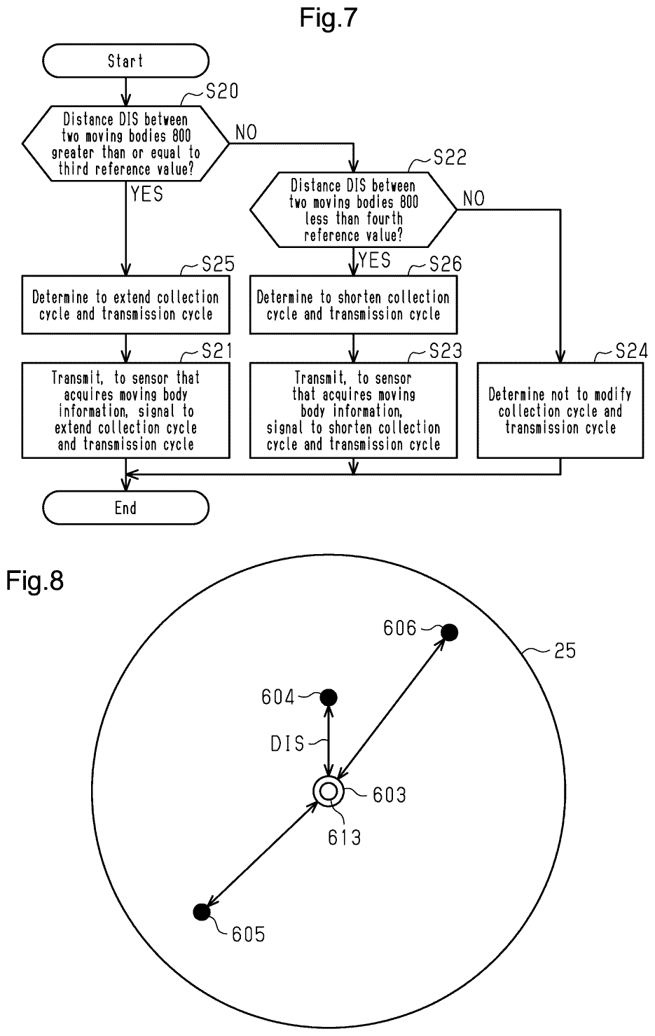

The collection cycle and the transmission cycle in the second embodiment will now be described with reference to FIGS. 7 and 8. FIG. 7 is a flowchart illustrating a series of processes executed by the processing device 100 of the information processing system 10. The first storage circuitry 102 of the processing device 100 stores a program that causes the first processing circuitry 101 to execute the series of processes. The processing device 100 executes the series of processes shown in FIG. 7 according to the program stored in the first storage circuitry 102. The series of processes is executed repeatedly by the information processing system 10 at regular intervals.

FIG. 8 illustrates one of the zones for which the information processing system 10 determines the collection cycle and the transmission cycle for a sensor. FIG. 8 illustrates a fifth zone 25 that is set for the third vehicle 603. In the second embodiment, the information processing system 10 sets a zone for each moving body 800. The third vehicle 603 includes a third vehicle on-board sensor 613. The third vehicle on-board sensor 613 collects the moving body information of the third vehicle 603. The third vehicle on-board sensor 613 transmits the moving body information of the third vehicle 603 to the information processing system 10. The third vehicle 603 corresponds to the first moving body 801 in the second embodiment. The fifth zone 25 corresponds to the zone set for the first moving body 801.

The fifth zone 25 contains a fourth vehicle 604, a fifth vehicle 605, and a sixth vehicle 606, as indicated by black circles, in addition to the third vehicle 603. In the fifth zone 25, the fourth vehicle 604 corresponds to another moving body 800 closest to the third vehicle 603.

The fourth vehicle 604 is located within the fifth zone 25 set for the third vehicle 603, which is the first moving body 801. The fourth vehicle 604 is the moving body 800 closest to the third vehicle 603, which is the first moving body 801. That is, the fourth vehicle 604 is the second moving body 802 in the second embodiment.

Upon starting the series of processes shown in FIG. 7, in the process of step S20, the processing device 100 acquires the distance DIS between the moving body 800 and another moving body 800, which is closest to the moving body 800 within the zone set for the moving body 800. That is, in the process of step S20, the processing device 100 acquires the distance DIS between the first moving body 801 and the second moving body 802. The processing device 100 determines whether the distance DIS is greater than or equal to a third reference value. In the second embodiment, the information processing system 10 sets the third reference value to ΔT1. When the distance DIS between the moving body 800 and the other moving body 800, which is closest to the moving body 800 within the zone set for the moving body 800, is greater than or equal to the third reference value (step S20: YES), the process proceeds to step S25. In the process of step S25, the information processing system 10 determines to extend the collection cycle and the transmission cycle for the sensor that acquires the moving body information of the moving body 800 for which the zone has been set. The process then proceeds to step S21. In the process of step S21, the information processing system 10 transmits a signal to extend the collection cycle and the transmission cycle to the sensor that acquires the moving body information of the moving body 800 for which the zone has been set. Then, the information processing system 10 terminates the process.

As shown in FIG. 8, in the fifth zone 25, the fourth vehicle 604 corresponds to another moving body 800, which is closest to the third vehicle 603. When the distance DIS between the third vehicle 603 and the fourth vehicle 604 is, for example, ΔT1, the information processing system 10 executes the process shown in FIG. 7 and then determines to extend the collection cycle and the transmission cycle for the third vehicle on-board sensor 613. Subsequently, the information processing system 10 transmits a signal to the third vehicle on-board sensor 613 to extend the collection cycle and the transmission cycle for the third vehicle on-board sensor 613. As a result, the cycle for acquiring the moving body information of the third vehicle 603 by the information processing system 10 is extended.

In the series of processes shown in FIG. 7, when the distance DIS between the moving body 800 and the other moving body 800, which is closest to the moving body 800 within the zone set for the moving body 800, is less than the third reference value (step S20: NO), the process proceeds to step S22. In the process of step S22, the information processing system 10 determines whether the distance DIS between the moving body 800 and the other moving body 800, which is closest to the moving body 800 within the zone set for the moving body 800, is less than a fourth reference value. The fourth reference value is less than the third reference value. In the second embodiment, the information processing system 10 sets the fourth reference value to ΔT2. ΔT2 is a shorter distance than ΔT1. When the distance DIS between the moving body 800 and the other moving body 800, which is closest to the moving body 800 within the zone set for the moving body 800, is less than the fourth reference value (step S22: YES), the process proceeds to step S26. For example, when the distance DIS between the moving body 800 and the other moving body 800, which is closest to the moving body 800 within the zone set for the moving body 800, is ΔT3, which is shorter than ΔT2, the process proceeds to step S26. In the process of step S26, the information processing system 10 determines to shorten the collection cycle and the transmission cycle for the sensor that acquires the moving body information of the moving body 800 for which the zone has been set. The process then proceeds to step S23. In the process of step S23, the information processing system 10 transmits a signal to shorten the collection cycle and the transmission cycle to the sensor that acquires the moving body information of the moving body 800 for which the zone has been set. Then, the information processing system 10 terminates the process.

As shown in FIG. 8, in the fifth zone 25, the fourth vehicle 604 corresponds to another moving body 800, which is closest to the third vehicle 603. When the distance DIS between the third vehicle 603 and the fourth vehicle 604 is, for example, ΔT3, the information processing system 10 executes the process shown in FIG. 7 and then determines to shorten the collection cycle and the transmission cycle for the third vehicle on-board sensor 613. Subsequently, the information processing system 10 transmits a signal to the third vehicle on-board sensor 613 to shorten the collection cycle and the transmission cycle. As a result, the cycle for acquiring the moving body information of the third vehicle 603 by the information processing system 10 is shortened.

In the series of processes shown in FIG. 7, when the distance DIS between the moving body 800 and the other moving body 800, which is closest to the moving body 800 within the zone set for the moving body 800, is greater than or equal to the fourth reference value (step S22: NO), the process proceeds to step S24. For example, when the distance DIS between the moving body 800 and the other moving body 800, which is closest to the moving body 800 within the zone set for the moving body 800, is ΔT2, the process proceeds to step S24. In the process of step S24, the information processing system 10 determines not to extend the collection cycle and the transmission cycle for the sensor that acquires the moving body information of the moving body 800 for which the zone has been set. In this case, the information processing system 10 does not transmit a signal to a sensor that acquires the moving body information of the moving body 800 for which the zone has been set. Then, the information processing system 10 terminates the process.

As shown in FIG. 8, in the fifth zone 25, the fourth vehicle 604 corresponds to another moving body 800, which is closest to the third vehicle 603. When the distance DIS between the third vehicle 603 and the fourth vehicle 604 is, for example, ΔT2, the information processing system 10 executes the process shown in FIG. 7 and then determines not to modify the collection cycle and the transmission cycle for the third vehicle on-board sensor 613. In this case, the information processing system 10 does not transmit a signal to the third vehicle on-board sensor 613. As a result, the cycle for acquiring the moving body information of the vehicle 603 by the information processing system 10 is not modified.

### Operation of Second Embodiment

When the distances DIS between moving bodies 800 are relatively short, the density of the moving bodies 800 is relatively high. When the distances DIS between the moving bodies 800 are relatively short, the information processing system 10 needs to acquire moving body information often to accurately recognize the position of each moving body 800. When the density of the moving bodies 800 is relatively low, the distances DIS between the moving bodies 800 are often relatively long. In such a case, the information processing system 10 has a low necessity to accurately determine the position of each moving body 800. This allows the information processing system 10 to extend the cycle for acquiring moving body information.

### Advantages of Second Embodiment

(2-1) The information processing system 10 properly determines the cycle for acquiring moving body information. This reduces the processing load on the information processing system 10 that acquires the predicted moving body information based on the moving body information.

(2-2) When the distance DIS between a moving body 800 and another moving body 800, which is closest to that moving body 800, is relatively long, the likelihood that the behavior of the other moving body 800 will affect the behavior of that moving body 800 is relatively low. Thus, even if the cycle for acquiring moving body information is relatively long, the information processing system 10 acquires accurate predicted moving body information for each moving body 800. Therefore, the information processing system 10 extends the cycle for acquiring moving body information on condition that the distance DIS between the moving body 800 and the other moving body 800, which is closest to the moving body 800, is greater than or equal to a set reference value. This reduces the processing load on the information processing system 10 that acquires the predicted moving body information based on the moving body information.

(2-3) When the distances DIS between moving bodies 800 are relatively short, the information processing system 10 needs to acquire moving body information at a higher frequency to accurately reproduce the positions of the moving bodies 800 in the virtual space that correspond to those in the real world. When the information processing system 10 has a relatively short cycle for acquiring moving body information, the amount of moving body information acquired per unit time by the information processing system 10 increases. To solve this problem, the information processing system 10 shortens the cycle for acquiring moving body information on condition that the distance DIS between the moving body 800 and the other moving body 800, which is closest to the moving body 800, is less than the reference value. This allows the information processing system 10 to accurately reproduce the position of each moving body 800 in the virtual space without increasing the processing load.

### Modification of Second Embodiment

The above-described second embodiment may be modified as follows. The present embodiment and the following modifications can be combined if the combined modifications remain technically consistent with each other.

In the second embodiment, the information processing system 10 sets two reference values; namely, the third reference value and the fourth reference value. The information processing system 10 may be configured to set only one reference value. For example, the information processing system 10 may set the reference value to ΔT2. In this case, when the distance DIS between the third vehicle 603 and the fourth vehicle 604 as shown in FIG. 8 is greater than or equal to ΔT2, the information processing system 10 determines to extend the collection cycle and the transmission cycle for the third vehicle on-board sensor 613. Subsequently, the information processing system 10 transmits a signal to the third vehicle on-board sensor 613 to extend the collection cycle and the transmission cycle. When the distance DIS between the third vehicle 603 and the fourth vehicle 604 as shown in FIG. 8 is less than ΔT2, the information processing system 10 determines to shorten the collection cycle and the transmission cycle for the third vehicle on-board sensor 613. Subsequently, the information processing system 10 transmits a signal to the third vehicle on-board sensor 613 to shorten the collection cycle and the transmission cycle.

After determining not to modify the collection cycle and the transmission cycle for the sensor that acquires the moving body information of the moving body 800 for which the zone has been set, the information processing system 10 may transmit a signal to the sensor, indicating that the collection cycle and the transmission cycle will not be modified. In such cases, the cycle at which the information processing system 10 acquires moving body information from the sensor will not be modified. The signal indicating no change will be made is, for example, a signal transmitted to a sensor to continue collecting and transmitting moving body information at the collection cycle and the transmission cycle in which the sensor is currently executing.

The third reference value and the fourth reference value are not limited to those in the above-described embodiment. In the information processing system 10, the reference value may be set to any distance in order to transmit suitable collection cycle and transmission cycle to sensors.

The information processing system 10 may change the range of the zone set for a moving body 800 depending on the travel direction of the moving body 800. For example, the information processing system 10 may broaden the zone set for a moving body 800 depending on the travel direction of the moving body 800. The information processing system 10 may change the range of the zone set for a moving body 800 depending on the speed SPD of the moving body 800. For example, the information processing system 10 may broaden the zone set for a moving body 800 as the speed SPD of the moving body 800 increases.

### Third Embodiment

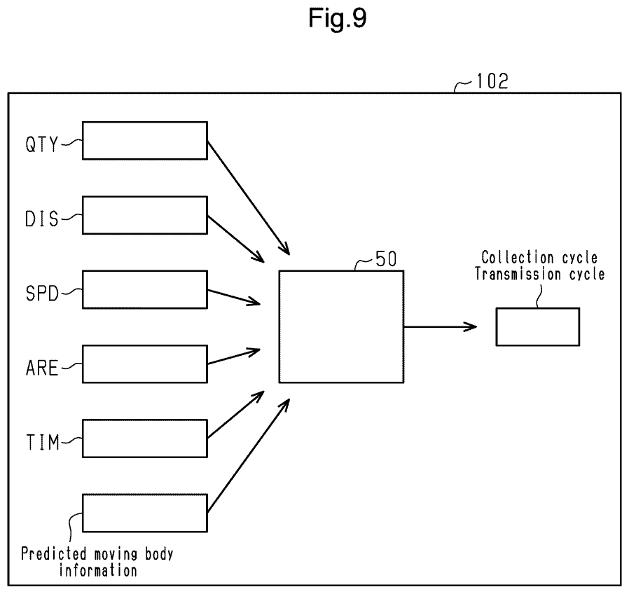

A third embodiment will now be described with reference to FIG. 9. The third embodiment will be described, with a focus on the differences from the first and second embodiments. In the third embodiment, the information processing system 10 synchronizes the collection times of multiple sensors located within a set zone in the same manner as the first embodiment. The information processing system 10 aligns the collection cycles of the sensors located within the set zone. The information processing system 10 synchronizes the transmission times of the sensors located within the set zone. The information processing system 10 aligns the transmission cycles of the sensors located within the set zone. As a result, the information processing system 10 acquires the moving body information of the moving bodies 800 located within the set zone from the sensors at the same time and at the same cycle.

### Trained Model 50

As shown in FIG. 9, the first storage circuitry 102 of the processing device 100 stores a trained model 50. The trained model 50 is one that has undergone supervised learning. In this model, when the information related to the density of moving bodies 800 located within the set zone is received as an explanatory variable, the collection cycle and the transmission cycle are output as objective variables.

For the supervised learning of the trained model 50, a large volume of training data is used. This data includes combinations of moving body information acquired from various zones and the suitable collection cycle and transmission cycle corresponding to the moving body information. The training data may be generated by labeling, for the moving body information, the collection cycle and the transmission cycle assumed as suitable. The training data may be generated by labeling, for the moving body information, the collection cycle and the transmission cycle that permit the deviation between the predicted moving body information for a time acquired from moving body information and the states of real-world moving bodies 800 at that time.

The information processing system 10 inputs the moving body information acquired from the sensor into the trained model 50, and executes a generation process that generates the collection cycle and the transmission cycle.

Explanatory Variable Input into Trained Model 50

The explanatory variable input into the trained model 50 includes the information related to the density of the moving body 800. The information related to the density of the moving body 800 is, for example, the number QTY of moving bodies 800 located per unit area. The information processing system 10 acquires the area of a set zone and the number QTY of moving bodies 800 located within that zone. The information processing system 10 acquires the number QTY of the moving bodies 800 per unit area, based on the area of the set zone and the number QTY of the moving bodies 800 located within that zone. The number QTY of moving bodies 800 per unit area is one of the factors that determine the collection cycle and the transmission cycle for a sensor.

The explanatory variable input into the trained model 50 includes information on the distances DIS between multiple moving bodies 800 located within a zone. The information on the distances DIS between multiple moving bodies 800 is one of the factors that determine the collection cycle and the transmission cycle for a sensor.

The explanatory variable input into the trained model 50 includes information on the speeds SPD of multiple moving bodies 800 located within a zone. The information on the speeds of moving bodies 800 is one of the factors that determine the collection cycle and the transmission cycle for a sensor.

### Explanatory Variables Indicating Characteristics of Region ARE

The explanatory variables input into the trained model 50 include variables that indicate the characteristics of a region ARE, which is contained within the zone where moving bodies 800 are located. The zone includes a region ARE, such as those in front of stations or urban districts, where moving bodies 800 are expected to move in a complex manner due to repeated starts and stops. When the moving body 800 moves in a complex manner, it is desirable to shorten the collection cycle and the transmission cycle for the sensor. The zone includes a region ARE, such as mountain roads, where the movement of the moving body 800 is expected to be simple. In a case in which the movement of the moving body 800 is simple, even if the collection cycle and the transmission cycle for the sensor are extended, the information processing system 10 acquires accurate predicted moving body information for the moving body 800. That is, the characteristics of the region ARE are included in the factors that determine the collection cycle and the transmission cycle for a sensor.

### Explanatory Variables Indicating Time Period TIM for Acquiring Moving Body Information

The explanatory variable input into the trained model 50 includes a variable indicating a time period TIM during which the moving body information was acquired. The state of the moving body 800 in the set zone may vary depending on the real-world time period TIM. For example, the number of moving bodies 800 within the set zone during the daytime is expected to be larger than that during the nighttime hours. For example, the number of moving bodies 800 within the set zone during the time period TIM in commuting hours is expected to be relatively large. That is, the time period TIM for acquiring moving body information is one of the factors that determine the collection cycle and the transmission cycle for a sensor.

### Explanatory Variable Related to the Density of Moving Body 800 in Predicted Moving Body Information

The explanatory variable input to the trained model 50 includes information related to the density of moving bodies 800 within the predicted moving body information on multiple moving bodies 800 located in the set zone. The predicted moving body information on multiple moving bodies 800 located in the set zone indicates the predicted position and predicted behavior of each moving body 800 at a time after the moving body information of the moving bodies 800 in the set zone was acquired. Examples of the information related to the density of the moving body 800 within the predicted moving body information include the number QTY of moving bodies 800 per unit area, the distances DIS between multiple moving bodies 800, and the speeds SPD of the moving bodies 800. The information related to the density of moving bodies 800 within the predicted moving body information is one of the factors that determine the collection cycle and the transmission cycle for a sensor.

### Determination of Collection Cycle and Transmission Cycle by the Information Processing System 10

The information processing system 10 transmits the collection cycle and the transmission cycle determined by the trained model 50 to the sensors located within the set zone. The information processing system 10 transmits the set collection time and transmission time to the sensors located within the set zone. After receiving the collection time, the collection cycle, the transmission time, and the transmission cycle, each of the sensors collects the moving body information within the set zone at the same time according to the collection cycle. Then, each of the sensors transmits the collected moving body information to the information processing system 10 at the same time according to the transmission cycle. As a result, the information processing system 10 acquires moving body information at the determined transmission cycle.

### Operation of the Third Embodiment

The information processing system 10 determines the collection cycle and the transmission cycle for each sensor by inputting the number QTY of moving bodies 800 per unit area, which is the information related to the density of the moving bodies 800, to the trained model 50 as an explanatory variable.

### Advantages of Third Embodiment

(3-1) The information processing system 10 uses the trained model 50, which has undergone supervised learning, to determine the cycle for acquiring moving body information based on the information related to the density of moving bodies 800. This reduces the processing load on the information processing system 10 that acquires the predicted moving body information based on the moving body information.

(3-2) When the distances DIS between multiple moving bodies 800 are relatively short, the information processing system 10 needs to shorten the cycle for acquiring the moving body information of the moving bodies 800 to accurately recognize the positions of the moving bodies 800. For this reason, the information processing system 10 uses the distances DIS between multiple moving bodies 800 as an explanatory variable for the trained model 50. Accordingly, the information processing system 10 determines the cycle for acquiring moving body information based on the distances DIS between multiple moving bodies 800.

(3-3) When the speed SPD of a moving body 800 is relatively high, a change in the position of the moving body 800 per unit time is greater compared to when the speed SPD of the moving body 800 is relatively low. When the change in the position of the moving body 800 is relatively large, the information processing system 10 needs to shorten the cycle for acquiring the moving body information of the moving body 800 in order to accurately reproduce its position in the virtual space. For this reason, the information processing system 10 uses the speed SPD of moving bodies 800 located within a zone as an explanatory variable for the trained model 50. Accordingly, the information processing system 10 determines the cycle for acquiring moving body information based on the speeds DIS of the moving bodies 800.

(3-4) The set zone may include the region ARE where moving bodies 800 move in a complex manner. In this case, the information processing system 10 needs to acquire moving body information in a relatively short cycle to accurately recognize the position of each moving body 800. The set zone may also include the region ARE where moving bodies 800 move in a simple manner. In this case, the information processing system 10 can accurately recognize the positions of the moving bodies 800 even after extending the cycle for acquiring the moving body information. For this reason, the information processing system 10 uses the characteristics of the region ARE as an explanatory variable for the trained model 50. Accordingly, the information processing system 10 determines the cycle for acquiring moving body information based on the characteristics of the region ARE.

(3-5) The number of moving bodies 800 within the set zone is relatively large depending on the time period TIM. Thus, the information processing system 10 needs to acquire moving body information in a relatively short cycle to accurately recognize the position of each moving body 800. The number of moving bodies 800 within the set zone is relatively small depending on the time period TIM. Thus, the information processing system 10 can accurately recognize the positions of the moving bodies 800 even after extending the cycle for acquiring the moving body information. For this reason, the information processing system 10 uses the time period TIM for acquiring moving body information as an explanatory variable for the trained model 50. Accordingly, the information processing system 10 determines the cycle for acquiring moving body information based on the time period TIM for acquiring moving body information.

(3-6) The information related to the density of moving bodies 800 in the set zone acquired by the information processing system 10 based on moving body information may be different from the information related to the density of moving bodies 800 in the set zone acquired by the information processing system 10 based on predicted moving body information. For this reason, the information processing system 10 uses the information related to the density of moving bodies 800, which is included in the predicted moving body information, as an explanatory variable for the trained model 50. Accordingly, the information processing system 10 determines the cycle for acquiring moving body information in the set zone based on the information related to the density of moving bodies 800, which is included in the predicted moving body information.

### Modification of Third Embodiment

The third embodiments may be modified as follows. The present embodiment and the following modifications can be combined if the combined modifications remain technically consistent with each other.

The processing device 100 of the information processing system 10 may store a relational equation instead of the trained model 50. The equation is predefined to output the collection cycle and the transmission cycle when receiving data that contains the information related to the density of moving bodies 800 as an explanatory variable. The information processing system 10 may also determine a suitable cycle as the cycle for acquiring moving body information using the predefined relational equation. This reduces the processing load on the information processing system 10 that acquires the predicted moving body information based on the moving body information.

The information processing system 10 may use basic statistical measures related to the distances DIS between multiple moving bodies 800 as explanatory variables. These measures serve as the information on the distances DIS between moving bodies 800 located within a set zone. For example, the information processing system 10 may use the mean of the distances DIS between multiple moving bodies 800 as an explanatory variable. The mean serves as the information on the distances DIS between moving bodies 800 located within a set zone. Instead, the information processing system 10 may use the maximum of the distances DIS between multiple moving bodies 800 as an explanatory variable. The maximum serves as the information on the distances DIS between moving bodies 800 located within a set zone. Alternatively, the information processing system 10 may use the minimum of the distances DIS between multiple moving bodies 800 as an explanatory variable. The minimum serves as the information on the distances DIS between moving bodies 800 located within a set zone. The information processing system 10 may combine multiple basic statistical measures related to the distances DIS between multiple moving bodies 800 and use the measures as explanatory variables.

The information processing system 10 may use basic statistical measures related to the speeds SPD of multiple moving bodies 800 as explanatory variables. These measures serve as the information on the speeds SPD between moving bodies 800 located within a set zone. For example, the information processing system 10 may use the mean of the speeds SPD of multiple moving bodies 800 as an explanatory variable. The mean serves as the information on the speeds SPD of moving bodies 800 located within a set zone. Instead, the information processing system 10 may use the maximum of the speeds SPD of multiple moving bodies 800 as an explanatory variable. The maximum serves as the information on the speeds SPD of moving bodies 800 located within a set zone. Alternatively, the information processing system 10 may use the minimum of the speeds SPD of multiple moving bodies 800 as an explanatory variable. The minimum serves as the information on the speeds SPD of moving bodies 800 located within a set zone. The information processing system 10 may combine multiple basic statistical measures related to the speeds SPD of multiple moving bodies 800 and use the measures as explanatory variables.

The types of explanatory variables are not limited to those in the above-described embodiment. For example, the types of explanatory variables are not limited to six. There may be five types of explanatory variables. There may be seven or more explanatory variables.

In the same manner as the second embodiment, the information processing system 10 may determine a unique collection cycle and transmission cycle for each sensor. For example, the information processing system 10 may input explanatory variables based on the moving body information acquired from the sensor into the trained model 50, thereby outputting a collection cycle and transmission cycle suitable for the sensor.

### Another Modification

The following are elements that can be modified and are generally applicable to each of the above-described embodiments. The following modification can be combined as long as the combined modification remains technically consistent with each other.

In each embodiment, the information processing system 10 determines the collection cycle and transmission cycle for each sensor. Subsequently, the information processing system 10 transmits a signal to each sensor based on the determined collection cycle and transmission cycle. The information processing system 10 may determine only the transmission cycle for each sensor. In this case, the information processing system 10 transmits a signal to each sensor based on the determined transmission cycle. For example, the information processing system 10 may determine only to extend the transmission cycle for each sensor. In this case, the information processing system 10 transmits a signal to the sensor to extend the transmission cycle. Extending only the transmission cycle for the sensor reduces the amount of moving body information acquired by the information processing system 10. This reduces the processing load on the information processing system 10 that acquires the predicted moving body information based on the moving body information.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. An information processing system configured to:
acquire moving body information at a set cycle, the moving body information indicating a position of each of multiple moving bodies located in the real world;
calculate predicted moving body information based on the moving body information, the predicted moving body information indicating a predicted position of each of the moving bodies at a time after the moving body information was acquired;
acquire, using the moving body information, information related to a density of the moving bodies located within a set zone; and
determine the cycle using the information related to the density.

2. The information processing system according to claim 1, wherein the information processing system is configured to:
acquire, as the information related to the density, an area of the zone and the number of the moving bodies located within the zone;
make the cycles for acquiring the moving body information of the moving bodies within the zone identical and determine the identical cycle based on the area and the number of the moving bodies; and
make the times at which the moving body information of the moving bodies starts to be acquired identical and determine the identical time.

3. The information processing system according to claim 2, wherein the information processing system is configured to:
set a reference value according to a size of the area; and
extend the cycle when the number of the moving bodies is less than the reference value.

4. The information processing system according to claim 2, wherein the information processing system is configured to:
set a reference value according to a size of the area; and
shorten the cycle when the number of the moving bodies is greater than or equal to the reference value.

5. The information processing system according to claim 1, wherein
the zone is set for a first moving body, the first moving body being one of the moving bodies, and
the information processing system is configured to:
acquire a distance between the first moving body and a second moving body as the information related to the density, the second moving body being one of the moving bodies located within the zone and being closest to the first moving body; and
determine the cycle for acquiring the moving body information of the moving bodies based on the distance.

6. The information processing system according to claim 5, wherein
the information processing system is configured to extend the cycle when the distance is greater than or equal to a set reference value.

7. The information processing system according to claim 5, wherein
the information processing system is configured to shorten the cycle when the distance is less than a set reference value.

8. The information processing system according to claim 1, wherein
the information processing system stores a trained model that has undergone supervised learning to output a suitable cycle when receiving data that contains the information related to the density as an explanatory variable, and
the information processing system is configured to output the suitable cycle by inputting, into the trained model, the data that contains the information related to the density as the explanatory variable.

9. The information processing system according to claim 1, wherein
the information processing system stores a relational equation predefined to output a suitable cycle when receiving data that contains the information related to the density as an explanatory variable, and
the information processing system is configured to output the suitable cycle by inputting, into the relational equation, the data that contains the information related to the density as the explanatory variable.

10. The information processing system according to claim 8, wherein
the data that contains the information related to the density as the explanatory variable further includes, as the explanatory variable, at least one of:
information on distances between the moving bodies within the zone;
information on speeds of the moving bodies within the zone;
a variable indicating characteristics of a region where the moving bodies are located;
a variable indicating a time period during which the moving body information was acquired; and
the information related to the density of the moving bodies in the predicted moving body information.

11. The information processing system according to claim 9, wherein
the data that contains the information related to the density as the explanatory variable further includes, as the explanatory variable, at least one of:
information on distances between the moving bodies within the zone;
information on speeds of the moving bodies within the zone;
a variable indicating characteristics of a region where the moving bodies are located;
a variable indicating a time period during which the moving body information was acquired; and
the information related to the density of the moving bodies in the predicted moving body information.

12. An information processing method, comprising:
acquiring moving body information at a set cycle, the moving body information indicating a position of each of multiple moving bodies located in the real world;
calculating predicted moving body information based on the moving body information, the predicted moving body information indicating a predicted position of each of the moving bodies at a time after the moving body information was acquired;
acquiring, using the moving body information, information related to a density of the moving bodies located within a set zone; and
determining the cycle using the information related to the density.

13. A non-transitory storage medium that stores an information processing program, wherein
the information processing program causes processing circuitry to execute:
acquiring moving body information at a set cycle, the moving body information indicating a position of each of multiple moving bodies located in the real world;
calculating predicted moving body information based on the moving body information, the predicted moving body information indicating a predicted position of each of the moving bodies at a time after the moving body information was acquired;
acquiring, using the moving body information, information related to a density of the moving bodies located within a set zone; and
determining the cycle using the information related to the density.
